(19) United States
(12) Patent Application Publication
(10) Pub. No.: US 2023/0105525 A1
(43) Pub. Date: Apr. 6, 2023

(54) NITRIDE SEMICONDUCTOR LIGHT-EMITTING ELEMENT

(71) Applicant: NIKKISO CO., LTD., Tokyo (JP)

(72) Inventors: Yusuke MATSUKURA, Ishikawa (JP); Cyril PERNOT, Ishikawa (JP)

(73) Assignee: NIKKISO CO., LTD., Tokyo (JP)

(21) Appl. No.: 17/948,453

(22) Filed: Sep. 20, 2022

(30) Foreign Application Priority Data
Sep. 21, 2021 (JP) 2021-153330

(51) Int. Cl. H01L 33/32; H01L 33/14

(52) U.S. Cl. CPC H01L 33/32; H01L 33/145

(57) ABSTRACT

A nitride semiconductor light-emitting element includes an n-type semiconductor layer; a p-type semiconductor layer; an active layer provided between the n-type semiconductor layer and the p-type semiconductor layer; and an electron blocking layer provided between the active layer and the p-type semiconductor layer. At least one of the p-type semiconductor layer and the electron blocking layer includes an oxygen-containing portion including oxygen. An oxygen concentration at each position of the oxygen-containing portion in a stacking direction of the n-type semiconductor layer, the active layer, the electron blocking layer and the p-type semiconductor layer is not less than 2.5×10¹⁶ atoms/cm³.

### CROSS-REFERENCE TO RELATED APPLICATIONS

The present patent application claims the priority of Japanese patent application No. 2021/153330 filed on Sep. 21, 2021, and the entire contents of Japanese patent application No. 2021/153330 are hereby incorporated by reference.

### TECHNICAL FIELD

The present invention relates to a nitride semiconductor light-emitting element.

### BACKGROUND ART

Patent Literature 1 discloses a light-emitting element which includes a high-concentration n-type group III nitride layer, a multiple quantum well structure, an i-type group III nitride final barrier layer, an electron blocking layer, and a p-type group III nitride layer in this order. The light-emitting element described in Patent Literature 1 has such a configuration to improve light output of the light light-emitting element.

### CITATION LIST

### Patent Literature

Patent Literature 1: JP 2010/205767A

### SUMMARY OF INVENTION

In case of the invention described in Patent Literature 1, there is room for improvement in terms of improving light output of the nitride semiconductor light-emitting element.

The invention was made in view of such circumstances and it is an object of the invention to provide a nitride semiconductor light-emitting element capable of improving light output.

To achieve the object described above, the invention provides a nitride semiconductor light-emitting element, comprising:
an n-type semiconductor layer;
a p-type semiconductor layer;
an active layer provided between the n-type semiconductor layer and the p-type semiconductor layer; and
an electron blocking layer provided between the active layer and the p-type semiconductor layer,
wherein at least one of the p-type semiconductor layer and the electron blocking layer comprises an oxygen-containing portion comprising oxygen, and
wherein an oxygen concentration at each position of the oxygen-containing portion in a stacking direction of the n-type semiconductor layer, the active layer, the electron blocking layer and the p-type semiconductor layer is not less than 2.5×10¹⁶ atoms/cm³.

### Advantageous Effects of Invention

According to the invention, it is possible to provide a nitride semiconductor light-emitting element capable of improving light output.

### BRIEF DESCRIPTION OF DRAWINGS

FIG. 1 is a schematic diagram illustrating a configuration of a nitride semiconductor light-emitting element in an embodiment.

FIG. 2 is a graph showing oxygen concentration distribution and Al secondary ion intensity distribution in a stacking direction for each of light-emitting elements in Comparative Example and Example.

FIG. 3 is a graph showing silicon concentration distribution and Al secondary ion intensity distribution in the stacking direction for each of the light-emitting elements in Comparative

Example and Example.

FIG. 4 is a graph showing magnesium concentration distribution and Al secondary ion intensity distribution in the stacking direction for each of the light-emitting elements in Comparative Example and Example.

FIG. 5 is a graph showing hydrogen concentration distribution and Al secondary ion intensity distribution in the stacking direction for each of the light-emitting elements in Comparative Example and Example.

FIG. 6 is a graph showing initial light output and residual light output in Comparative Example and Example.

### DESCRIPTION OF EMBODIMENTS

### Embodiment

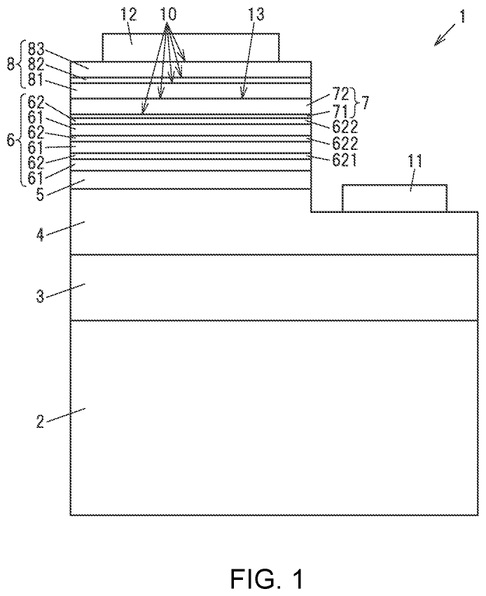

An embodiment of the invention will be described in reference to the FIG. 1. The embodiment below is described as a preferred illustrative example for implementing the invention. Although some part of the embodiment specifically illustrates various technically preferable matters, the technical scope of the invention is not limited to such specific aspects.

### Nitride Semiconductor Light-Emitting Element 1

FIG. 1 is a schematic diagram illustrating a configuration of a nitride semiconductor light-emitting element 1 in the present embodiment. In FIG. 1, the scale ratio of each layer of the nitride semiconductor light-emitting element 1 (hereinafter, also simply referred to as “the light-emitting element 1”) in a stacking direction is not necessarily the same as the actual scale ratio.

The light-emitting element 1 constitutes, e.g., a light-emitting diode (LED) or a semiconductor laser (LD: laser diode). In the present embodiment, the light-emitting element 1 constitutes a light-emitting diode (LED) that emits light with a wavelength in an ultraviolet region. Particularly, the light-emitting element 1 in the present embodiment constitutes a deep ultraviolet LED that emits deep ultraviolet light at a central wavelength of not less than 200 nm and not more than 365 nm. The light-emitting element 1 in the present embodiment can be used in fields such as, e.g., sterilization (e.g., air purification, water purification, etc.), medical treatment (e.g., light therapy, measurement/analysis, etc.), UV curing, etc.

The light-emitting element 1 includes a buffer layer 3, an n-type cladding layer 4 (the n-type semiconductor layer), a composition gradient layer 5, an active layer 6, an electron blocking layer 7 and a p-type semiconductor layer 8 in this order on a substrate 2. Each layer on the substrate 2 can be formed by a well-known epitaxial growth method such as the Metal Organic Chemical Vapor Deposition (MOCVD) method, the Molecular Beam Epitaxy (MBE) method, or Hydride Vapor Phase Epitaxy (HVPE) method. The light-emitting element 1 also includes an n-side electrode 11 provided on the n-type cladding layer 4, and a p-side electrode 12 provided on the p-type semiconductor layer 8.

Hereinafter, a direction of stacking the substrate 2, the buffer layer 3, the n-type cladding layer 4, the composition gradient layer 5, the active layer 6, the electron blocking layer 7 and the p-type semiconductor layer 8 (an up-and-down direction in FIG. 1) is simply referred to as “a stacking direction”. In addition, one side of the substrate 2 where each layer of the light-emitting element 1 is stacked (i.e., an upper side in FIG. 1) is referred to as the upper side, and the opposite side (i.e., a lower side in FIG. 1) is referred to as the lower side. The terms “upper” and “lower” are used for descriptive purposes and do not limit the posture of the light-emitting element 1 with respect to the vertical direction when, e.g., the light-emitting element 1 is in use. Each layer constituting the light-emitting element 1 has a thickness in the stacking direction.

As semiconductors constituting the light-emitting element 1, it is possible to use, e.g., binary to quaternary group III nitride semiconductors expressed by AlₓGa_{y}In_{1-x-y}N (0≤x≤1, 0≤y≤1, 0≤x+y≤1). In deep ultraviolet LEDs, Al_{z}G_{1-z}N system (0≤z≤1) not including indium is often used. The group III elements in semiconductors constituting the light-emitting element 1 may be partially substituted with boron (B) or thallium (Tl), etc. In addition, nitrogen (N) may be partially substituted with phosphorus (P), arsenic (As), antimony (Sb) or bismuth (Bi), etc. Next, each constituent element of the light-emitting element 1 will be described.

### Substrate 2

The substrate 2 is made of a material transparent to light (deep ultraviolet light in the present embodiment) emitted by the active layer 6. The substrate 2 is, e.g., a sapphire (Al₂O₃) substrate. Alternatively, e.g., an aluminum nitride (AlN) substrate or an aluminum gallium nitride (AlGaN) substrate, etc., may be used as the substrate 2.

### Buffer Layer 3

The buffer layer 3 is formed on the substrate 2. In the present embodiment, the buffer layer 3 is made of aluminum nitride. When the substrate 2 is an aluminum nitride substrate or an aluminum gallium nitride substrate, the buffer layer 3 may not be necessarily included.

### N-Type Cladding Layer 4

The n-type cladding layer 4 is formed on the buffer layer 3. The n-type cladding layer 4 is an n-type semiconductor layer made of, e.g., AlₐGa₁₋ₐN (0≤a≤1) doped with an n-type impurity. An Al composition ratio a of the n-type cladding layer 4 is, e.g., preferably not less than 20%, and is more preferably not less than 25% and not more than 70%. In this regard, the Al composition ratio is also called AlN mole fraction.

The n-type cladding layer 4 is an n-type semiconductor layer doped with silicon (Si) as an n-type impurity. Alternatively, germanium (Ge), selenium (Se) or tellurium (Te), etc., may be used as the n-type impurity. The same applies to the semiconductor layers containing an n-type impurity other than the n-type cladding layer 4. The n-type cladding layer 4 has a film thickness of not less than 1 μm and not more than 4 μm. The n-type cladding layer 4 may have a single layer structure or may have a multilayer structure.

### Composition Gradient Layer 5

The composition gradient layer 5 is formed on the n-type cladding layer 4. The composition gradient layer 5 is made of Al_{b}Ga_{1-b}N (0≤b≤1). In the composition gradient layer 5, an Al composition ratio at each position in the stacking direction is higher at an upper position. The composition gradient layer 5 may have a very small region in the stacking direction (e.g., a region of not more than 5% of the entire composition gradient layer 5 in the stacking direction) in which an Al composition ratio does not increase toward the upper side.

The composition gradient layer 5 is preferably configured such that the Al composition ratio at its lower end portion is substantially the same (e.g., a difference within 5%) as the Al composition ratio of the n-type cladding layer 4 and the Al composition ratio at its upper end portion is substantially the same (e.g., a difference within 5%) as an Al composition ratio of a barrier layer 61 adjacent to the composition gradient layer 5. By providing the composition gradient layer 5, it is possible to prevent a sudden change in the Al composition ratio between the barrier layer 61 and the n-type cladding layer 4 which are adjacent to the composition gradient layer 5 on the upper and lower sides. Occurrence of dislocations caused by lattice mismatch can thus be suppressed. As a result, it is possible to suppress consumption of electrons and holes due to non-luminescent recombination in the active layer 6, and light output of the light-emitting element 1 is improved. A film thickness of the composition gradient layer 5 can be, e.g., not less than 5 nm and not more than 20 nm. Silicon as an n-type impurity is preferably contained in the composition gradient layer 5 in the present embodiment, but it is not limited thereto.

### Active Layer 6

The active layer 6 is formed on the composition gradient layer 5. In the present embodiment, the active layer 6 is formed to have a multiple quantum well structure which includes plural well layers 62. In the present embodiment, the active layer 6 has three barrier layers 61 and three well layers 62 which are alternately stacked. In the active layer 6, the barrier layer 61 is located at the lower end and the well layer 62 is located at the upper end. The active layer 6 generates light at a predetermined wavelength by recombination of electrons with holes in the multiple quantum well structure. In the present embodiment, the active layer 6 is configured to have a band gap of not less than 3.4 eV so that deep ultraviolet light at a wavelength of not more than 365 nm is output. Particularly in the present embodiment, the active layer 6 is configured so that deep ultraviolet light at a central wavelength of not less than 200 nm and not more than 365 nm can be generated.

Each barrier layer 61 is made of Al_{c}Ga_{1-c}N (0≤c≤1). The Al composition ratio c of each barrier layer 61 can be, e.g., not less than 75% and not more than 95%. Each barrier layer 61 has a film thickness of not less than 2 nm and not more than 12 nm.

Each well layer 62 is made of Al_{d}Ga_{1-d}N (0≤d≤1). The three well layers 62 in the present embodiment are configured such that a lowermost well layer 621, which is the well layer 62 formed at the farthest position from the p-type semiconductor layer 8, has a different configuration from upper-side well layers 622 which are two well layers 62 other than the lowermost well layer 621.

A film thickness of the lowermost well layer 621 is not less than 1 nm greater than a film thickness of each of the upper-side well layers 622. In the present embodiment, the lowermost well layer 621 has a film thickness of not less than 4 nm and not more than 6 nm, and each upper-side well layer 622 has a film thickness of not less than 2 nm and not more than 4 nm. A difference between the film thickness of the lowermost well layer 621 and the film thickness of each upper-side well layer 622 can be, e.g., not less than 2 nm and not more than 4 nm. The film thickness of the lowermost well layer 621 can be, e.g., not less than double and not more than three times the film thickness of the upper-side well layer 622. By increasing the film thickness of the lowermost well layer 621 to larger than the film thickness of the upper-side well layers 622, the lowermost well layer 621 is flattened and flatness of each layer formed on the lowermost well layer 621 in the active layer 6 is also improved. As a result, it is possible to suppress variation in the Al composition ratio in each layer of the active layer 6 and it is possible to improve monochromaticity of output light.

An Al composition ratio of the lowermost well layer 621 is not less than 2% greater than an Al composition ratio of each of the two upper-side well layers 622. In the present embodiment, the lowermost well layer 621 has an Al composition ratio of not less than 35% and not more than 55%, and each upper-side well layer 622 has an Al composition ratio of not less than 25% and not more than 45%. A difference between the Al composition ratio of the lowermost well layer 621 and the Al composition ratio of each upper-side well layer 622 can be, e.g., not less than 10% and not more than 30%. The Al composition ratio of the lowermost well layer 621 can be, e.g., not less than 1.4 times and not more than 2.2 times the Al composition ratio of the upper-side well layer 622. By increasing the Al composition ratio of the lowermost well layer 621 to higher than the Al composition ratio of the upper-side well layers 622, a difference in the Al composition ratio between the n-type cladding layer 4 and the lowermost well layer 621 is reduced and crystallinity of the lowermost well layer 621 is improved. Then, the improved crystallinity of the lowermost well layer 621 improves crystallinity of each layer formed on the lowermost well layer 621 in the active layer 6. As a result, carrier mobility in the active layer 6 is improved and intensity of output light is improved.

In addition, e.g., the lowermost well layer 621 may be doped with silicon as an n-type impurity. This leads to formation of V-pits in the active layer 6, and such V-pits serve to stop advance of dislocations from the n-type cladding layer 4 side. In this regard, the upper-side well layers 622 may also contain an n-type impurity such as silicon. In addition, the active layer 6 has a multiple quantum well structure in the present embodiment but may have a single quantum well structure having only one well layer 62.

### Electron Blocking Layer 7

The electron blocking layer 7 serves to improve efficiency of electron injection into the active layer 6 by suppressing occurrence of the overflow phenomenon in which electrons leak from the active layer 6 to the p-type semiconductor layer 8. In the present embodiment, the electron blocking layer 7 is made of AlₑGa₁₋ₑN (0.7≤e≤1). That is, in the present embodiment, an Al composition ratio e of the electron blocking layer 7 is not less than 70%. The electron blocking layer 7 has a first layer 71 and a second layer 72 which are stacked in this order from the lower side.

The first layer 71 is provided so as to be in contact with the upper-side well layer 622 located uppermost in the active layer 6. The first layer 71 preferably has an Al composition ratio of not less than 80% and the first layer 71 in the present embodiment is made of aluminum nitride (i.e., an Al composition ratio of 100%). The higher the Al composition ratio, the higher the electron blocking effect of suppressing passage of electrons. Thus, by forming the first layer 71 with a high Al composition ratio at a position adjacent to the active layer 6, a high electron blocking effect is obtained at a position close to the active layer 6 and this makes it easy to ensure electron existence probability in the three well layers 62.

Here, if a film thickness of the first layer 71 with a high Al composition ratio is increased excessively, there is concern that an electrical resistance value of the entire light-emitting element 1 becomes excessively large. For this reason, the film thickness of the first layer 71 is preferably not less than 0.5 nm and not more than 10 nm, more preferably, not less than 0.5 nm and not more than 5 nm. On the other hand, if the film thickness of the first layer 71 is reduced, it can increase the probability that electrons pass through the first layer 71 from the lower side to the upper side due to the tunnel effect. Therefore, in the light-emitting element 1 of the present embodiment, the second layer 72 is formed on the first layer 71 to suppress passage of electrons through the entire electron blocking layer 7.

The second layer 72 has an Al composition ratio smaller than the Al composition ratio of the first layer 71. The Al composition ratio of the second layer 72 can be, e.g., not less than 70% and not more than 90%. Meanwhile, a film thickness of the second layer 72 is preferably not less than the film thickness of the first layer 71 and is preferably not less than 1 nm and less than 100 nm from the viewpoint of ensuring that the sufficient electron blocking effect is obtained and also the electrical resistance value is reduced.

A film thickness of the electron blocking layer 7, i.e., a total film thickness of the first layer 71 and the second layer 72 can be not less than 15 nm and not more than 100 nm. Magnesium as a p-type impurity, which is diffused from the p-type semiconductor layer 8 toward the active layer 6 when power is supplied to the light-emitting element 1, easily reaches the active layer 6 particularly when the film thickness of the entire electron blocking layer 7 is not more than 100 nm. Then, when magnesium diffused from the p-type semiconductor layer 8 toward the active layer 6 easily reaches the active layer 6, hydrogen is also easily diffused into the active layer 6 at the same time since hydrogen is likely to bond with magnesium. When magnesium is diffused into the active layer 6, dislocations are likely to occur in the active layer 6 due to a difference in atomic radius between atoms of the matrix constituting the active layer 6 and magnesium. If it occurs, recombination of electrons with holes in the active layer 6 is likely to become non-luminescent recombination (e.g., recombination that generates vibration), which may decrease luminous efficiency. Meanwhile, when hydrogen is diffused into the active layer 6, the active layer 6 may deteriorate, resulting in that light output decreases as power supply time elapses, and life of the light-emitting element 1 may be shortened.

Therefore, in the present embodiment, an average value of a hydrogen concentration in the stacking direction over the entire electron blocking layer 7 is not more than 2.0×10¹⁸ atoms/cm³, preferably not more than 1.0×10¹⁸ atoms/cm³. Since the hydrogen concentration in the electron blocking layer 7 is relatively low, bonding of hydrogen to magnesium diffused from the p-type semiconductor layer 8 toward the active layer 6 can be suppressed and diffusion of hydrogen into the active layer 6 can thereby be suppressed.

Adjustment of the hydrogen concentration in each layer of the electron blocking layer 7 can be achieved by, e.g., adjusting a magnesium concentration in each layer of the electron blocking layer 7. That is, hydrogen is likely to be attracted to magnesium, hence, e.g., lowering the magnesium concentration in each layer of the electron blocking layer 7 allows the hydrogen concentration in each layer of the electron blocking layer 7 to be lowered. From the viewpoint of lowering the hydrogen concentration in each layer of the electron blocking layer 7, the magnesium concentration at each position of each layer of the electron blocking layer 7 in the stacking direction is preferably not more than 5.0×10¹⁸ atoms/cm³ and is more preferably at the background level. The magnesium concentration at the background level is a magnesium concentration detected when magnesium is not doped.

Each layer of the electron blocking layer 7 has an oxygen-containing portion 10 containing oxygen (O). An oxygen concentration in each layer of the electron blocking layer 7 will be described later. In the present embodiment, each layer of the electron blocking layer 7 does not contain impurities other than oxygen.

However, each layer of the electron blocking layer 7 may contain impurities other than oxygen. For example, each layer of the electron blocking layer 7 can be a layer containing an n-type impurity other than oxygen, a layer containing a p-type impurity, or a layer containing both an n-type impurity and a p-type impurity. When each layer of the electron blocking layer 7 contains an impurity, the impurity in each layer of the electron blocking layer 7 may be contained in the entire portion of each layer of the electron blocking layer 7 or may be contained in a part of each layer of the electron blocking layer 7. Magnesium (Mg) can be used as the p-type impurity to be included in each layer of the electron blocking layer 7, but zinc (Zn), beryllium (Be), calcium (Ca), strontium (Sr), barium (Ba) or carbon (C), etc., may be used other than magnesium. In addition, in the entire electron blocking layer 7, an average of each impurity concentration in the stacking direction is preferably not more than 5.0×10¹⁸ atoms/cm³. The reach of hydrogen, which is diffused from the p-type semiconductor layer 8 toward the active layer 6, to the active layer 6 is suppressed by lowering the impurity concentrations in each layer of the electron blocking layer 7. The electron blocking layer 7 may alternatively be composed of a single layer.

### Boundary Portion 13 Between Electron Blocking Layer 7 and P-Type Semiconductor Layer 8

A boundary portion 13 between the electron blocking layer 7 and the p-type semiconductor layer 8 contains silicon as an n-type impurity. Silicon contained in the boundary portion 13 is provided to suppress diffusion of magnesium and hydrogen from the p-type semiconductor layer 8 into the active layer 6. That is, since the boundary portion 13 between the electron blocking layer 7 and the p-type semiconductor layer 8 contains silicon, magnesium in the p-type semiconductor layer 8 is stopped by silicon in the boundary portion 13. Diffusion of magnesium contained in the p-type semiconductor layer 8 into the active layer 6 is thereby suppressed. In this regard, a p-type impurity and an n-type impurity, particularly magnesium and silicon, are likely to be attracted to each other. Furthermore, since hydrogen is likely to bond with magnesium, diffusion of hydrogen from the p-type semiconductor layer 8 into the active layer 6 is also suppressed by suppressing diffusion of magnesium from the p-type semiconductor layer 8 into the active layer 6. In this regard, magnesium is often used as a p-type impurity in group III-V semiconductors.

Silicon in the boundary portion 13 should be present in at least one of the following states: a solid solution state in the crystal; a cluster state; and a state in which a compound containing silicon is precipitated. The solid solution state of silicon in the crystal is a state in which silicon is doped in aluminum gallium nitride constituting the boundary portion 13, i.e., a state in which silicon is located at lattice positions of aluminum gallium nitride. Meanwhile, the cluster state of silicon is a state in which silicon excessively doped in aluminum gallium nitride constituting the boundary portion 13 is present at the lattice positions of aluminum gallium nitride and is also present as aggregates, etc., between the lattice positions. The state in which a compound containing silicon is precipitated is a state in which, e.g., silicon nitride, etc., is formed. In the boundary portion 13 between the electron blocking layer 7 and the p-type semiconductor layer 8, a silicon-containing layer may be formed or silicon-containing portions may be scattered in a plane direction orthogonal to the stacking direction.

In silicon concentration distribution in the stacking direction of the light-emitting element 1, a peak value of a silicon concentration in the boundary portion 13 preferably satisfies not less than 1.0×10¹⁸ atoms/cm³ and not more than 1.0×10²⁰ atoms/cm³.By setting to not less than 1.0×10¹⁸ atoms/cm³, it is easy to further suppress diffusion of magnesium. Meanwhile, by setting to not more than 1.0×10²⁰ atoms/cm³, it is possible to suppress a decrease in crystallinity of the second layer 72 and a first p-type cladding layer 81 which are adjacent to the boundary portion 13. Furthermore, in the silicon concentration distribution in the stacking direction of the light-emitting element 1, the peak value of the silicon concentration in the boundary portion 13 more preferably satisfies not less than 3.0×10¹⁸ atoms/cm³ and not more than 5.0×10¹⁹ atoms/cm³. Then, by configuring such that the electron blocking layer 7 located between the boundary portion 13 containing silicon and the active layer 6 is formed as a layer containing little impurities as described above and the p-type semiconductor layer 8 located on the opposite side to the active layer 6 relative to the boundary portion 13 is formed as a layer containing a relatively large amount of a p-type impurity, it is possible to suppress diffusion of magnesium and hydrogen from the p-type semiconductor layer 8 into the active layer 6 while increasing a carrier concentration in the p-type semiconductor layer 8.

### P-Type Semiconductor Layer 8

The p-type semiconductor layer 8 is formed on the second layer 72. In the present embodiment, an Al composition ratio of the p-type semiconductor layer 8 is less than 70%. In the present embodiment, the p-type semiconductor layer 8 has the first p-type cladding layer 81, a second p-type cladding layer 82 and a p-type contact layer 83 which are stacked in this order from the lower side. Each of the first p-type cladding layer 81, the second p-type cladding layer 82 and the p-type contact layer 83 has the oxygen-containing portion 10 containing oxygen. Oxygen concentrations in the first p-type cladding layer 81, the second p-type cladding layer 82 and the p-type contact layer 83 will be described later.

The first p-type cladding layer 81 is provided so as to be in contact with the second layer 72. The first p-type cladding layer 81 is made of Al_{f}Ga_{1-f}N (0≤f≤1) containing magnesium as a p-type impurity. A magnesium concentration in the first p-type cladding layer 81 can be not less than 1.0×10¹⁸ atoms/cm³ and not more than 1.0×10²⁰ atoms/cm³. An Al composition ratio f of the first p-type cladding layer 81 can be not less than 45% and not more than 65%. The first p-type cladding layer 81 has a film thickness of not less than 15 nm and not more than 35 nm.

The second p-type cladding layer 82 is made of Al_{g}Ga_{1-g}N (0≤g≤1) containing magnesium as a p-type impurity. A magnesium concentration in the second p-type cladding layer 82 can be not less than 1.0×10¹⁸ atoms/cm³ and not more than 1.0×10²⁰ atoms/cm³, in the same manner as the magnesium concentration in the first p-type cladding layer 81.

In the second p-type cladding layer 82, an Al composition ratio in the stacking direction decreases toward the upper side. In this regard, the second p-type cladding layer 82 may have a very small region in the stacking direction (e.g., a region of not more than 5% of the entire second p-type cladding layer 82 in the stacking direction) in which an Al composition ratio does not decrease toward the upper side.

The second p-type cladding layer 82 is preferably configured such that the Al composition ratio at its lower end portion is substantially the same (e.g., a difference within 5%) as the Al composition ratio of the first p-type cladding layer 81 and the Al composition ratio at its upper end portion is substantially the same (e.g., a difference within 5%) as an Al composition ratio of the p-type contact layer 83. A sudden change in the Al composition ratio between the p-type contact layer 83 and the first p-type cladding layer 81, which are adjacent to the second p-type cladding layer 82 on the upper and lower sides, is suppressed by providing the second p-type cladding layer 82. Occurrence of dislocations caused by lattice mismatch can thereby be suppressed. As a result, it is possible to suppress consumption of electrons and holes due to non-luminescent recombination in the active layer 6 and light output of the light-emitting element 1 is improved. A film thickness of the second p-type cladding layer 82 can be, e.g., not less than 2 nm and not more than 4 nm.

The p-type contact layer 83 is a layer connected to the p-side electrode 12 and is made of AlₕGa₁₋ₕN (0≤h≤1) doped with a high concentration of magnesium as a p-type impurity. A magnesium concentration in the p-type contact layer 83 can be not less than 5.0×10¹⁸ atoms/cm³ and not more than 5.0×10²¹ atoms/cm³. In the present embodiment, the p-type contact layer 83 is made of p-type gallium nitride (GaN). The p-type contact layer 83 is configured to have a low Al composition ratio h to achieve an ohmic contact with the p-side electrode 12 and, from such a viewpoint, is preferably made of p-type gallium nitride. A film thickness of the p-type contact layer 83 can be, e.g., not less than 10 nm and not more than 25 nm.

The p-type impurity contained in each layer of the p-type semiconductor layer 8 is magnesium, but may be zinc, beryllium, calcium, strontium, barium or carbon, etc.

### N-Side Electrode 11

The n-side electrode 11 is formed on a surface of the n-type cladding layer 4 which is exposed on the upper side. The n-side electrode 11 can be made of, e.g., a multilayered film formed by sequentially stacking titanium (Ti), aluminum, titanium and gold (Au) on the n-type cladding layer 4.

### P-Side Electrode 12

The p-side electrode 12 is formed on the p-type contact layer 83. The p-side electrode 12 is a reflective electrode that reflects deep ultraviolet light emitted from the active later 6. The p-side electrode 12 has a reflectance of not less than 50%, preferably not less than 60%, at the central wavelength of light emitted by the active later 6. The p-side electrode 12 is preferably a metal containing rhodium (Rh). The metal containing rhodium is highly reflective of deep ultraviolet light and is also highly bondable to the p-type contact layer 83. In the present embodiment, the p-side electrode 12 is composed of a rhodium monolayer. Light emitted upward from the active layer 6 is reflected at an interface between the p-side electrode 12 and the p-type semiconductor layer 8.

In the present embodiment, the light-emitting element 1 is flip-chip mounted on a package substrate (not shown). That is, the light-emitting element 1 is mounted such that a side in the stacking direction, which is a side where the n-side electrode 11 and the p-side electrode 12 are provided, faces the package substrate and each of the n-side electrode 11 and the p-side electrode 12 is attached to the package substrate via a gold bump, etc. Light from the flip-chip mounted light-emitting element 1 is extracted on the substrate 2 side (i.e., on the lower side). However, it is not limited thereto and the light-emitting element 1 may be mounted on the package substrate by wire bonding, etc. In addition, although the light-emitting element 1 in the present embodiment is a so-called lateral light-emitting element 1 in which both the n-side electrode 11 and the p-side electrode 12 are provided on the upper side of the light-emitting element 1, the light-emitting element 1 is not limited thereto and may be a vertical light-emitting element 1. The vertical light-emitting element 1 is a light-emitting element 1 in which the active layer 6 is sandwiched between the n-side electrode 11 and the p-side electrode 12. In this regard, when the light-emitting element 1 is of the vertical type, the substrate 2 and the buffer layer 3 are preferably removed by laser lift-off, etc.

### Oxygen Concentrations in Electron Blocking Layer 7 and P-Type Semiconductor Layer 8

Each layer of the electron blocking layer 7 and each layer of the p-type semiconductor layer 8 have the oxygen-containing portion 10 containing oxygen. In the present embodiment, substantially the entire portion of each layer of the electron blocking layer 7 (i.e., the first layer 71 and the second layer 72) and substantially the entire portion of each layer of the p-type semiconductor layer 8 (i.e., the first p-type cladding layer 81, the second p-type cladding layer 82 and the p-type contact layer 83) are the oxygen-containing portion 10. Here, it is known that the carrier concentration in the p-type semiconductor layer 8 can be increased by annealing the light-emitting element 1 in an oxygen-containing atmosphere (JP 2013/128009 A). In the present embodiment, each layer of the electron blocking layer 7 and each layer of the p-type semiconductor layer 8 are deposited in an oxygen atmosphere so that each layer of the electron blocking layer 7 and each layer of the p-type semiconductor layer 8 become the oxygen-containing portions 10. Thus, annealing of the p-type semiconductor layer 8 in the oxygen atmosphere is advanced simultaneously with deposition of the p-type semiconductor layer 8, which increases the carrier concentration in the p-type semiconductor.

An oxygen concentration at each position of the oxygen-containing portion 10 in the stacking direction is not less than 2.5×10¹⁶ atoms/cm³. Furthermore, the oxygen concentration at each position of the oxygen-containing portion 10 in the stacking direction is not less than preferably 3.0×10¹⁶ atoms/cm³, more preferably not less than 4.0×10¹⁶ atoms/cm³, further preferably not less than 8.0×10¹⁶ atoms/cm³. The carrier concentration in the p-type semiconductor layer 8 can be higher when the oxygen concentration in the oxygen-containing portion 10 is higher. From such a viewpoint, an average value of the oxygen concentration in the stacking direction over the entire oxygen-containing portion 10 (the entire electron blocking layer 7 and the entire p-type semiconductor layer 8 in the present embodiment) is preferably not less than 1.4×10¹⁷ atoms/cm³. The average value of the oxygen concentration in the stacking direction over the entire oxygen-containing portion 10 is preferably higher than an average value of an oxygen concentration in the stacking direction over the n-type cladding layer 4 (the n-type semiconductor layer).

In addition, the average value of the oxygen concentration in the stacking direction over the entire oxygen-containing portion 10 can be equivalent to an average value of an oxygen concentration in the stacking direction over the active layer 6. When, e.g., the average value of the oxygen concentration in the stacking direction over the entire oxygen-containing portion 10 is not less than 0.8 times and not more than 1.2 times the average value of the oxygen concentration in the stacking direction over the active layer 6, these average values can be said to be equivalent. It is possible to improve crystallinity of the active layer 6, the electron blocking layer 7 and the p-type semiconductor layer 8 by uniformizing the oxygen concentration in the active layer 6, the electron blocking layer 7 and the p-type semiconductor layer 8 as described above.

From the viewpoint of increasing the oxygen concentration in each layer of the electron blocking layer 7, a p-type impurity concentration at each position of each layer of the electron blocking layer 7 in the stacking direction is preferably not more than 5.0×10¹⁹ atoms/cm³, more preferably not more than 1.0×10¹⁹ atoms/cm³, and further preferably at the background level. When the oxygen concentration in each layer of the electron blocking layer 7 increases, it is possible to suppress diffusion of hydrogen from the p-type semiconductor layer 8 into the active layer 6 through the electron blocking layer 7 (see WO 2012/140844, Specification, paragraph 0111).

The oxygen concentration in the p-type semiconductor layer 8 is less than a concentration of the p-type impurity in the p-type semiconductor layer 8. Since oxygen is an n-type impurity, the oxygen concentration in the p-type semiconductor layer 8 is less than the p-type concentration.

Meanwhile, the oxygen concentration at each position of the oxygen-containing portion 10 in the stacking direction is preferably not more than 5.0×10¹⁸ atoms/cm³. When the oxygen concentration at each position of the oxygen-containing portion 10 in the stacking direction is not more than 5.0×10¹⁸ atoms/cm³, deterioration of crystallinity of the oxygen-containing portion 10 is suppressed. From a similar viewpoint, the average value of the oxygen concentration in the stacking direction over the entire oxygen-containing portion 10 is preferably not more than 1.0×10¹⁸ atoms/cm^{3.}

Although each layer of the electron blocking layer 7 and each layer of the p-type semiconductor layer 8 are entirely formed as the oxygen-containing portion 10 in the present embodiment, it is not limited thereto. Only at least a portion of the electron blocking layer 7 and the p-type semiconductor layer 8 should be the oxygen-containing portion 10. For example, only a portion of one of the layers constituting the p-type semiconductor layer 8 may be the oxygen-containing portion 10. When, e.g., only a portion of the first p-type cladding layer 81 is the oxygen-containing portion 10, the oxygen-containing portion 10 may be formed in a layer shape or may be scattered in the first p-type cladding layer 81. The same applies to when the oxygen-containing portion 10 is formed in a portion of a layer other than the first p-type cladding layer 81. From the viewpoint of increasing the carrier concentration in the p-type semiconductor layer 8, it is preferable that at least the p-type semiconductor layer 8 include the oxygen-containing portion 10. However, even in case that the electron blocking layer 7 has the oxygen-containing portion 10 and the p-type semiconductor layer 8 does not have the oxygen-containing portion 10, it is possible to improve light output of the light-emitting element 1. That is, in this case, when some of p-type impurities in the p-type semiconductor layer 8 which do not contribute to p-type conductivity of the p-type semiconductor layer 8 try to diffuse toward the active layer 6 due to power supply, etc. , the p-type impurities are stopped by oxygen in the electron blocking layer 7 and diffusion of the p-type impurities into the active layer 6 is suppressed. This can suppress a decrease in crystallinity of the active layer 6, and as a result, luminescent coupling of the carrier is enhanced and light output of the light-emitting element 1 is improved. Meanwhile, from the viewpoint of suppressing diffusion of hydrogen from the p-type semiconductor layer 8 into the active layer 6 through the electron blocking layer 7, it is preferable that at least the electron blocking layer 7 include the oxygen-containing portion 10. It is more preferable that both the electron blocking layer 7 and the p-type semiconductor layer 8 include the oxygen-containing portion 10.

### Numerical Values of Element Concentrations

Numerical values of the above-described element concentrations (the oxygen concentration, the hydrogen concentration, the silicon concentration, etc. ) at each position of the light-emitting element 1 in the stacking direction are values obtained using secondary-ion mass spectrometry (SIMS). A method for measuring the element concentrations will be described since measurement results can vary greatly even when using secondary-ion mass spectrometry depending on the number and type, etc. , of elements for which element concentrations are measured simultaneously.

The following processes were separately performed to measure the element concentrations at each position of the light-emitting element 1 in the stacking direction: a process in which concentrations of the four elements: silicon, oxygen, carbon, and hydrogen, and secondary ion intensity of Al are measured simultaneously; and a process in which the magnesium concentration and secondary ion intensity of Al are measured simultaneously. PHI ADEPT1010 manufactured by ULVAC-PHI, Inc. can be used for measurement of these elements. In this regard, in secondary-ion mass spectrometry, it is not possible to accurately measure the element concentrations in a layer constituting the outermost surface (in the p-type contact layer 83 in the present embodiment), hence, the numerical values of the element concentrations (the oxygen concentration, the hydrogen concentration, the silicon concentration, etc. ) at each position of the light-emitting element 1 in the stacking direction described above are values which do not take into account the values measured in the region in which accurate measurement is impossible. The measurement conditions can be set as follows: use of Cs+ as a primary ion species, primary accelerating voltage of 2. 0 kV, and a detection area of 88×88 μm².

### Method for Manufacturing Light-Emitting Element 1

Next, a method for manufacturing the light-emitting element 1 in the present embodiment will be described.

In the present embodiment, the buffer layer 3, the n-type cladding layer 4, the composition gradient layer 5, the active layer 6, the first layer 71, the second layer 72, the first p-type cladding layer 81, the second p-type cladding layer 82 and the p-type contact layer 83 are epitaxially grown in this order on the substrate 2 by the Metal Organic Chemical Vapor Deposition (MOCVD) method. That is, in the present embodiment, the substrate 2 is placed in a chamber and each layer is formed on the substrate 2 by introducing high temperature carrier gases to be raw materials of each layer formed on the substrate 2, into the chamber. A growth temperature of the buffer layer 3 can be not less than 1000° C. and not more than 1400° C., a growth temperature of the n-type cladding layer 4 can be not less than 1020° C. and not more than 1180° C., a growth temperature of each of the composition gradient layer 5, the active layer 6, the first layer 71, the second layer 72, the first p-type cladding layer 81 and the second p-type cladding layer 82 can be not less than 1000° C. and not more than 1100° C., and a growth temperature of the p-type contact layer 83 can be not less than 900° C. and not more than 1100° C.

Each layer of the light-emitting element 1 is grown in a high temperature environment, as described above. In the present embodiment, both the electron blocking layer 7 and the p-type semiconductor layer 8 are the oxygen-containing portions 10 and are grown at high temperature in an oxygen-containing atmosphere. Therefore, annealing of the p-type semiconductor layer 8 in an oxygen atmosphere is also advanced during deposition of the p-type semiconductor layer 8, which increases the carrier concertation in the deposited p-type semiconductor layer 8. Meanwhile, bis(cyclopentadienyl)magnesium (Cp2Mg) to be a magnesium source is not supplied into a chamber when forming the electron blocking layer 7. The oxygen concentration at each portion of the electron blocking layer 7 and the p-type semiconductor layer 8 in the stacking direction can be thereby increased. In addition, it is also possible to increase the oxygen concentration at each portion of the electron blocking layer 7 and the p-type semiconductor layer 8 in the stacking direction by also supplying an oxygen gas into the chamber simultaneously with supplying the carrier gases to be raw materials of each layer during deposition of the electron blocking layer 7 and the p-type semiconductor layer 8.

### Functions and Effects of the Embodiment

In the present embodiment, at least one of the electron blocking layer 7 and the p-type semiconductor layer 8 has the oxygen-containing portion 10 in which the oxygen concentration at each position in the stacking direction is not less than 2.5×10¹⁶ atoms/cm³. Therefore, it is possible to improve light output of the light-emitting element 1. Firstly, in case that the p-type semiconductor layer 8 has the oxygen-containing portion 10, annealing of the p-type semiconductor layer 8 in the oxygen atmosphere is advanced simultaneously with deposition of the p-type semiconductor layer 8, hence, it is possible to easily increase the carrier concentration in the p-type semiconductor layer 8 without special measures to increase the carrier concentration. In this regard, even when the light-emitting element 1 is further annealed after growing each layer of the light-emitting element 1, the annealing process after growing each layer of the light-emitting element 1 can be shortened in the present embodiment since annealing of the p-type semiconductor layer 8 in the oxygen atmosphere is advanced simultaneously with deposition of the p-type semiconductor layer 8, as described above. Therefore, it is possible to increase the carrier concentration in the p-type semiconductor layer 8 and improve light output of the light-emitting element 1 while suppressing an increase in complexity of the process of manufacturing the light-emitting element or an increase in process time. Meanwhile, in case that the electron blocking layer 7 has the oxygen-containing portion 10, diffusion of the p-type impurity into the active layer 6 is suppressed by oxygen in the electron blocking layer 7 when some of p-type impurities in the p-type semiconductor layer 8 which do not contribute to p-type conductivity of the p-type semiconductor layer 8 try to diffuse toward the active layer 6 due to power supply, etc. This can suppress a decrease in crystallinity of the active layer 6, and as a result, luminescent coupling of the carrier is enhanced and light output of the light-emitting element 1 is improved. Furthermore, as described above, when the oxygen concentration in each layer of the electron blocking layer 7 increases, diffusion of hydrogen from the p-type semiconductor layer 8 into the active layer 6 through the electron blocking layer 7 can be suppressed, resulting in a longer life of the light-emitting element 1.

In addition, the oxygen-containing portion 10 is formed in at least the p-type semiconductor layer 8. Therefore, the atmosphere during deposition of the p-type semiconductor layer 8 tends to contain a large amount of oxygen and annealing of the p-type semiconductor layer 8 in the oxygen atmosphere can be further advanced. It is thereby possible to further increase the carrier concentration in the p-type semiconductor layer 8.

The oxygen-containing portion 10 is formed in at least the electron blocking layer 7. Therefore, it is possible to suppress diffusion of the p-type impurity and hydrogen from the p-type semiconductor layer 8 into the active layer 6 through the electron blocking layer 7. Light output and life of the light-emitting element 1 can thereby be increased.

In addition, in the oxygen-containing portion 10 of the electron blocking layer 7, the p-type impurity concentration at each position in the stacking direction is not more than 5.0×10¹⁹ atoms/cm³. Oxygen is less likely to enter the electron blocking layer 7 if the p-type impurity concentration in the electron blocking layer 7 is high, but it is easy to increase the oxygen concentration in the electron blocking layer 7 according to the present embodiment. It is thereby possible to suppress diffusion of the p-type impurity and hydrogen from the p-type semiconductor layer 8 into the active layer 6, and as a result, light output and life of the light-emitting element 1 can be increased.

In addition, the average value of the oxygen concentration in the stacking direction over the entire oxygen-containing portion 10 (from the first layer 71 to the p-type contact layer 83 in the present embodiment) is higher than the average value of the oxygen concentration in the stacking direction over the n-type semiconductor layer. Therefore, it is possible to ensure that the oxygen-containing portion 10 has a sufficient oxygen concentration, and it is thereby possible to further improve light output of the light-emitting element 1.

In addition, the boundary portion 13 between the electron blocking layer 7 and the p-type semiconductor layer 8 contains an n-type impurity (silicon in the present embodiment) other than oxygen. Therefore, the p-type impurity in the p-type semiconductor layer 8 is stopped by silicon in the boundary portion 13, which suppresses diffusion of the p-type impurity into the active layer 6. It is thereby possible to improve light output of the light-emitting element 1. Furthermore, since hydrogen is likely to bond with magnesium, diffusion of hydrogen from the p-type semiconductor layer 8 into the active layer 6 is also suppressed by suppressing diffusion of magnesium from the p-type semiconductor layer 8 into the active layer 6. As a result, a decrease in light output of the light-emitting element 1 with a lapse of power supply time can be suppressed and life of the light-emitting element 1 can be increased.

As described above, according to the present embodiment, it is possible to provide a nitride semiconductor light-emitting element capable of improving light output.

### Experimental Example

This Experimental Example is an example in which initial light output and residual light output were evaluated for Comparative Example, which is a light-emitting element with the electron blocking layer and the p-type semiconductor layer having a relatively low oxygen concentration, and for Example, which is a light-emitting element with the electron blocking layer and the p-type semiconductor layer having a relatively high oxygen concentration. Among constituent elements in this Experimental Example, the constituent elements denoted by the same names as those in the above-mentioned embodiment indicate the same constituent elements as those in the above-mentioned embodiment, unless otherwise specified.

Firstly, the light-emitting elements in Comparative Example and Example will be described. Table 1 shows film thickness, Al composition ratio, silicon concentration, magnesium concentration and oxygen concentration of each layer of the light-emitting element in Comparative Example, and Table 2 shows film thickness, Al composition ratio, silicon concentration, magnesium concentration and oxygen concentration of each layer of the light-emitting element in Example. The oxygen concentration from the first layer to the second p-type cladding layer in Tables 1 and 2 is the smallest value of the oxygen concentration from the first layer to the second p-type cladding layer in the stacking direction. In each of Comparative Example and Example, values of the oxygen concentration in the p-type contact layer constituting the outermost surface cannot be accurately measured and the detected results are shown as they are. In Tables 1 and 2, “BG” indicates the background level. In addition, the figure in the column of Al composition ratio for Composition gradient layer in Tables 1 and 2 indicates that the Al composition ratio of the composition gradient layer in the stacking direction gradually increases from 55% to 85% from the lower end to the upper end of the composition gradient layer. Likewise, the figure in the column of Al composition ration for Second p-type cladding layer in Tables 1 and 2 indicates that the Al composition ratio of the second p-type cladding layer in the stacking direction gradually decreases from 55% to 0% from the lower end to the upper end of the second p-type cladding layer.

TABLE 1

| | | | | Al | Si | Mg | O |
|---|---|---|---|---|---|---|---|
| Structure | | Film | | composition | concentration | concentration | concentration |
| (Comparative Example) | | thickness | | ratio [%] | [atoms/cm³] | [atoms/cm³] | [atoms/cm³] |
| Substrate | | 430 μm ± 25 μm | | — | BG | BG | BG |
| Buffer layer | | 2000 ± 200 | nm | 100 | BG | BG | BG |
| N-type cladding layer | | 2000 ± 200 | nm | 55 ± 10 | (1.50 ± 1.00)E+19 | BG | 1.50E+16 − 1.50E+17 |
| Composition | | 15 ± 5 | nm | 55→85 | BG − Peak | BG | 2.00E+16 − 2.00E+17 |
| gradient layer | | | | | concentration in | | |
| | | | | | Lowermost well layer | | |
| Active layer | Barrier | 7 ± 5 | nm | 85 ± 10 | BG − Peak | BG | 4.00E+16 − 2.50E+17 |
| (3QW) | layer | | | | concentration in | | |
| | | | | | Lowermost well layer | | |
| | Well layer | 5 ± 1 | nm | 45 ± 10 | Peak | BG | |
| | (Lowermost | | | | concentration: | | |
| | well layer) | | | | (3.50 ± 2.50)E+19 | | |
| | Barrier | 7 ± 5 | nm | 85 ± 10 | BG − Peak | BG | |
| | layer | | | | concentration in | | |
| | | | | | Lowermost well layer | | |
| | Well layer | 3 ± 1 | nm | 35 ± 10 | BG − 1.00E+19 | BG | |
| | (Upper-side | | | | | | |
| | well layer) | | | | | | |
| | Barrier layer | 7 ± 5 | nm | 85 ± 10 | BG − 1.00E+19 | BG − 1.00E+19 | |
| | Well layer | 3 ± 1 | nm | 35 ± 10 | BG − 1.00E+18 | BG − 1.00E+19 | |
| | (Upper-side | | | | | | |
| | well layer) | | | | | | |
| Electron | First layer | 2 ± 1 | nm | 95 ± 5 | Peak concentration | BG − 5.00E+19 | 2.41E+16 |
| blocking layer | Second layer | 25 ± 10 | nm | 80 ± 10 | in Boundary portion | 1.00E+18 − 1.00E+20 | (Lowest |
| P-type | First p-type | 25 ± 10 | nm | 55 ± 10 | (2.00 ± 1.00)E+19 | 1.00E+18 − 1.00E+20 | concentration) |
| semiconductor | cladding layer | | | | Other than | | |
| layer | Second p-type | 3 ± 1 | nm | 55→0 | Boundary | 1.00E+18 − 1.00E+20 | |
| | cladding layer | | | | portion BG | | |
| | P-type | 20 ± 5 | nm | 0 | | 5.00E+18 − 5.00E+21 | BG − 5.00E+21 |
| | contact layer | | | | | | |

TABLE 2

| | | | | Al | Si | Mg | O |
|---|---|---|---|---|---|---|---|
| | | Film | | composition | concentration | concentration | concentration |
| Structure (Example) | | thickness | | ratio [%] | [atoms/cm³] | [atoms/cm³] | [atoms/cm³] |
| Substrate | | 430 μm ± 25 μm | | — | BG | BG | BG |
| Buffer layer | | 2000 ± 200 | nm | 100 | BG | BG | BG |
| N-type cladding layer | | 2000 ± 200 | nm | 55 ± 10 | (1.50 ± 1.00)E+19 | BG | 7.00E+15 − 1.50E+17 |
| Composition | | 15 ± 5 | nm | 55→85 | BG − Peak | BG | 5.00E+16 − 3.00E+17 |
| gradient layer | | | | | concentration in | | |
| | | | | | Lowermost well layer | | |
| Active layer | Barrier | 7 ± 5 | nm | 85 ± 10 | BG − Peak | BG | 5.00E+16 − 3.00E+17 |
| (3QW) | layer | | | | in concentration | | |
| | | | | | Lowermost well layer | | |
| | Well layer | 5 ± 1 | nm | 45 ± 10 | Peak | BG | |
| | (Lowermost | | | | concentration: | | |
| | well layer) | | | | (3.50 ± 2.50)E+19 | | |
| | Barrier | 7 ± 5 | nm | 85 ± 10 | BG − Peak | BG | |
| | layer | | | | concentration in | | |
| | | | | | Lowermost well layer | | |
| | Well layer | 3 ± 1 | nm | 35 ± 10 | BG − 1.00E+19 | BG | |
| | (Upper-side | | | | | | |
| | well layer) | | | | | | |
| | Barrier layer | 7 ± 5 | nm | 85 ± 10 | BG − 1.00E+19 | BG | |
| | Well layer | 3 ± 1 | nm | 35 ± 10 | BG − 1.00E+18 | BG | |
| | (Upper-side | | | | | | |
| | well layer) | | | | | | |
| Electron | First layer | 2 ± 1 | nm | 95 ± 5 | Peak concentration | BG | 8.41E+16 |
| blocking layer | Second layer | 25 ± 10 | nm | 80 ± 10 | in Boundary portion | BG | (Lowest |
| P-type | First p-type | 25 ± 10 | nm | 55 ± 10 | (2.00 ± 1.00)E+19 | 1.00E+18 − 1.00E+20 | concentration) |
| semiconductor | cladding layer | | | | Other than | | |
| layer | Second p-type | 3 ± 1 | nm | 55→0 | Boundary | 1.00E+18 − 1.00E+20 | |
| | cladding layer | | | | portion BG | | |
| | P-type | 20 ± 5 | nm | 0 | | 5.00E+18 − 5.00E+21 | BG − 5.00E+21 |
| | contact layer | | | | | | |

The Al composition ratio of each layer shown in Tables 1 and 2 is a value estimated from secondary ion intensity of Al measured by SIMS. As understood from Tables 1 and 2, the lowest value of the oxygen concentration from the first layer to the second p-type cladding layer in the stacking direction in Comparative Example is 2.41×10¹⁶ atoms/cm³, and the lowest value of the oxygen concentration from the first layer to the second p-type cladding layer in the stacking direction in Example is 8.41×10¹⁶ atoms/cm³. In addition, magnesium is contained in the electron blocking layer in Comparative Example, but magnesium is not contained in the electron blocking layer in Example. In Comparative Example, magnesium can be also detected in the barrier layer and the upper-side well layer closest to the second p-type cladding layer due to the influence of magnesium contained in the electron blocking layer. The main differences between Comparative Example and Example are as described above.

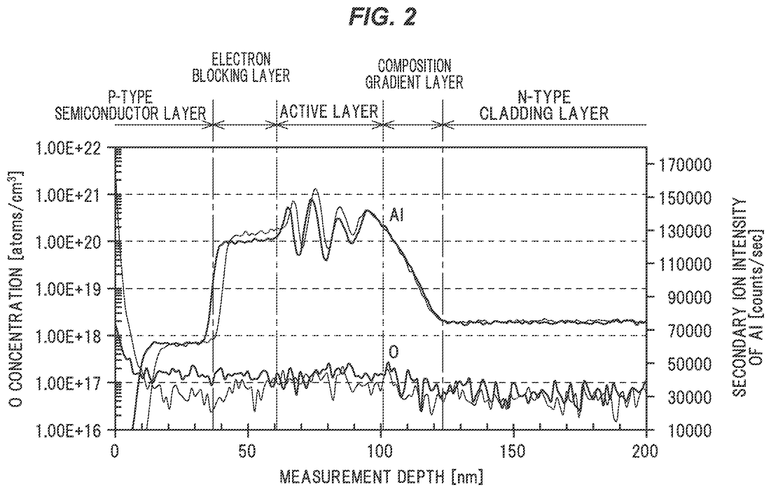

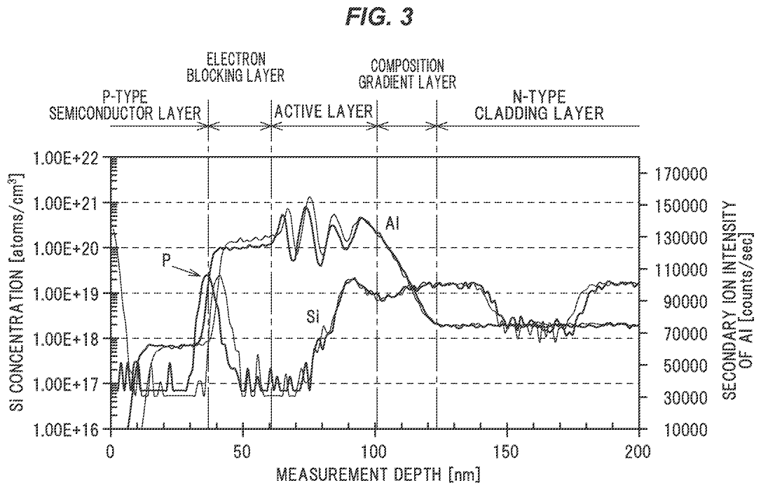

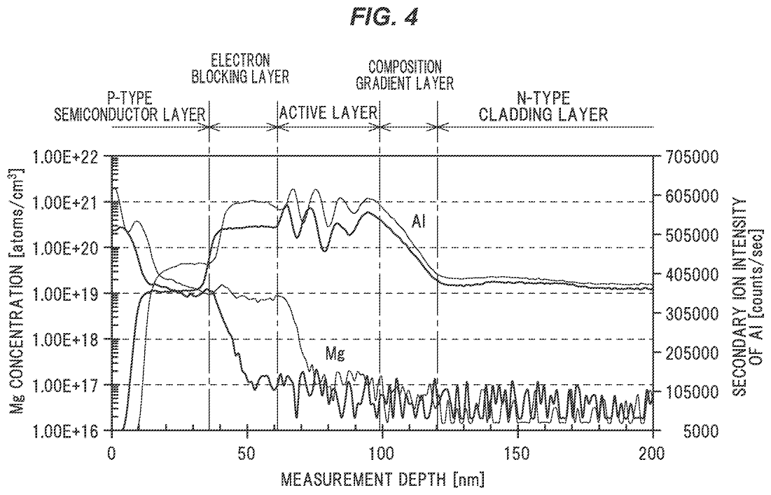

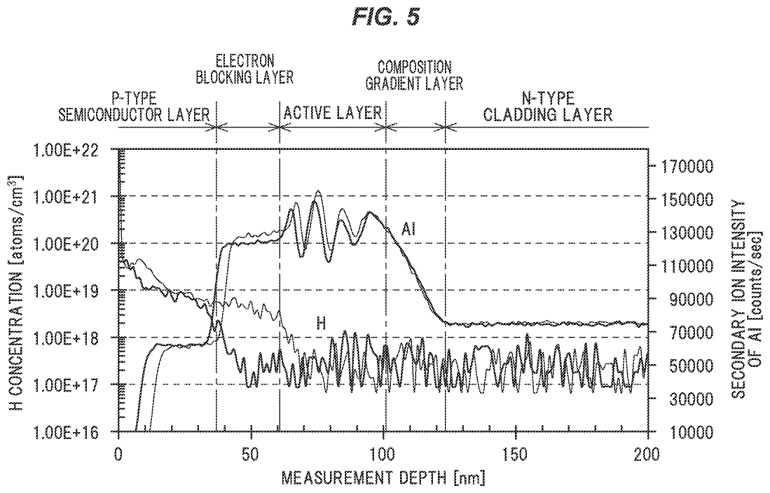

FIG. 2 shows oxygen concentration distribution and Al secondary ion intensity distribution in the stacking direction for each of the light-emitting elements in Comparative Example and Example. FIG. 3 shows silicon concentration distribution and Al secondary ion intensity distribution in the stacking direction for each of the light-emitting elements in Comparative Example and Example. FIG. 4 shows magnesium concentration distribution and Al secondary ion intensity distribution in the stacking direction for each of the light-emitting elements in Comparative Example and Example. FIG. 5 shows hydrogen concentration distribution and Al secondary ion intensity distribution in the stacking direction for each of the light-emitting elements in Comparative Example and Example. In FIGS. 2 to 5, measurement results in Example are indicated by thick lines and measurement results in Comparative Example are indicated by thin lines. Rough locations of boundaries of the respective layers of the light-emitting element in Example are shown in FIGS. 2 to 5.

In FIG. 3, a peak P of the silicon concentration emerges at a boundary portion between the electron blocking layer and the p-type semiconductor layer. Here, the peak P in FIG. 3 appears to have some width, but this is a matter of measurement and the thickness of the silicon-containing portion of the boundary portion is actually substantially zero. In addition, comparison of FIGS. 4 and 5 shows that the hydrogen concentration increases or decreases together with the magnesium concentration. For example, the electron blocking layer in Comparative Example contains a relatively large amount of magnesium and thus has a relatively high hydrogen concentration, but the electron blocking layer in Example does not contain magnesium and thus has a low hydrogen concentration.

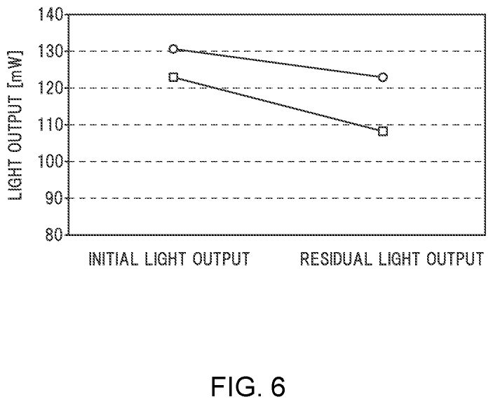

Initial light output and residual light output were also measured in each of Comparative Example and Example. The initial light output is light output when supplying a current of 350 mA to the light-emitting elements in Comparative Example and Example immediately after being manufactured. Meanwhile, the residual light output is light output of the light-emitting elements in Comparative Example and Example after continuously passing a current of 350 mA for 1000 hours. Measurement of light output was conducted by a photodetector placed under each of the light-emitting elements in Comparative Example and Example. The result is shown in the graph in FIG. 6. In FIG. 6, the results in Example are plotted with circles, and the results in Comparative Example are plotted with diamonds.

As understood from FIG. 6, both the initial light output and the residual light output of the light-emitting element in Example are higher than those of the light-emitting element in Comparative Example. In addition, the slope of the graph is smaller for the result of the light-emitting element in Example than for the light-emitting element in Comparative Example That is, the light-emitting element in Example deteriorates slower and has a longer life than the light-emitting element in Comparative Example.

### Summary of the embodiment

Technical ideas understood from the embodiment will be described below citing the reference signs, etc. , used for the embodiment. However, each reference sign, etc., described below is not intended to limit the constituent elements in the claims to the members, etc. , specifically described in the embodiment.

[1] The first aspect of the invention is a nitride semiconductor light-emitting element (1), comprising: an n-type semiconductor layer (4); a p-type semiconductor layer (8); an active layer (6) provided between the n-type semiconductor layer (4) and the p-type semiconductor layer (8); and an electron blocking layer (7) provided between the active layer (6) and the p-type semiconductor layer (8), wherein at least one of the p-type semiconductor layer (8) and the electron blocking layer (7) comprises an oxygen-containing portion (10) comprising oxygen, and wherein an oxygen concentration at each position of the oxygen-containing portion (10) in a stacking direction of the n-type semiconductor layer (4), the active layer (6), the electron blocking layer (7) and the p-type semiconductor layer (8) is not less than 2.5×10¹⁶ atoms/cm³.

It is thereby possible to improve light output of the nitride semiconductor light-emitting element.

[2] The second aspect of the invention is that, in the first aspect, the oxygen-containing portion (10) is formed in at least the p-type semiconductor layer (8).

It is thereby possible to further increase the carrier concentration in the p-type semiconductor layer.

[3] The third aspect of the invention is that, in the first or second aspect, the oxygen-containing portion (10) is formed in at least the electron blocking layer (7).

It is thereby possible to improve light output and increase life of the light-emitting element.

[4] The fourth aspect of the invention is that, in the third aspect, a p-type impurity concentration at each position of the oxygen-containing portion (10) of the electron blocking layer (7) in the stacking direction is not more than 5.0×10¹⁹ atoms/cm³.

It is thereby possible to improve light output and increase life of the light-emitting element.

[5] The fifth aspect of the invention is that, in any one of the first to fourth aspect, an average value of an oxygen concentration in the stacking direction over the entire oxygen-containing portion (10) is higher than an average value of an oxygen concentration in the stacking direction over the n-type semiconductor layer (4).

It is thereby possible to further improve light output of the light-emitting element.

[6] The sixth aspect of the invention is that, in any one of the first to fifth aspect, a boundary portion (13) between the p-type semiconductor layer (8) and the electron blocking layer (7) comprises an n-type impurity other than oxygen.

It is thereby possible to improve light output and increase life of the light-emitting element.

### Additional Note

Although the embodiment of the invention has been described, the invention according to claims is not to be limited to the embodiment described above. Further, please note that not all combinations of the features described in the embodiment are necessary to solve the problem of the invention. In addition, the invention can be appropriately modified and implemented without departing from the gist thereof.

### REFERENCE SIGNS LIST

1 LIGHT-EMITTING ELEMENT
10 OXYGEN-CONTAINING PORTION
13 BOUNDARY PORTION
4 N-TYPE CLADDING LAYER (N-TYPE SEMICONDUCTOR LAYER)
6 ACTIVE LAYER
7 ELECTRON BLOCKING LAYER
8 P-TYPE SEMICONDUCTOR LAYER

1. A nitride semiconductor light-emitting element, comprising:
an n-type semiconductor layer;
a p-type semiconductor layer;
an active layer provided between the n-type semiconductor layer and the p-type semiconductor layer; and
an electron blocking layer provided between the active layer and the p-type semiconductor layer,
wherein at least one of the p-type semiconductor layer and the electron blocking layer comprises an oxygen-containing portion comprising oxygen, and
wherein an oxygen concentration at each position of the oxygen-containing portion in a stacking direction of the n-type semiconductor layer, the active layer, the electron blocking layer and the p-type semiconductor layer is not less than 2.5×10¹⁶ atoms/cm³.

2. The nitride semiconductor light-emitting element according to claim 1, wherein the oxygen-containing portion is formed in at least the p-type semiconductor layer.

3. The nitride semiconductor light-emitting element according to claim 1, wherein the oxygen-containing portion is formed in at least the electron blocking layer.

4. The nitride semiconductor light-emitting element according to claim 3, wherein a p-type impurity concentration at each position of the oxygen-containing portion of the electron blocking layer in the stacking direction is not more than 5.0×10¹⁹ atoms/cm³.

5. The nitride semiconductor light-emitting element according to claim 1, wherein an average value of an oxygen concentration in the stacking direction over the entire oxygen-containing portion is higher than an average value of an oxygen concentration in the stacking direction over the n-type semiconductor layer.

6. The nitride semiconductor light-emitting element according to claim 1, wherein a boundary portion between the p-type semiconductor layer and the electron blocking layer comprises an n-type impurity other than oxygen.
